(19) United States
(12) Patent Application Publication
(10) Pub. No.: US 2026/0089865 A1
(43) Pub. Date: Mar. 26, 2026

(54) SLIDE RAIL DEVICE FOR A SERVER RACK

(71) Applicant: FOSITEK CORPORATION, New Taipei City (TW)

(72) Inventors: Chia-Hung SU, New Taipei City (TW); Hao-Ping WANG, New Taipei City (TW)

(73) Assignee: FOSITEK CORPORATION, New Taipei City (TW)

(21) Appl. No.: 19/001,864

(22) Filed: Dec. 26, 2024

(30) Foreign Application Priority Data
Sep. 20, 2024 (TW) 113135841

(51) Int. Cl. H05K 7/14

(52) U.S. Cl. CPC H05K 7/1489

(57) ABSTRACT

A slide rail device for connecting with a server case includes a middle rail and an inner rail unit. The inner rail unit includes an inner rail disposed on and longitudinally slidable along the middle rail and having an engaging slot for the engaging member to be transversely inserted thereinto, a lock member disposed on the inner rail to be engageable with the engaging member, and a releasing member operably moved longitudinally to abut and press the lock member to bring deflection of the lock member away from an inner rail surface of the inner rail so as to release engagement of the lock member from the engaging member.

### CROSS-REFERENCE TO RELATED APPLICATION

This application claims priority to Taiwanese Patent Application No. 113135841, filed on Sep. 20, 2024, and incorporated by reference herein in its entirety.

### FIELD

The disclosure relates to a slide rail device for a server rack, and more particularly to a slide rail device for connecting with a server case.

### BACKGROUND

In a conventional server rack, a releasably positioning structure is mounted to a slide rail device through a biasing member. A server case is connected with and mounted on the slide rail device and positioned thereon by means of T-type fasteners with biasing members. Hence, the biasing members need to be manually operated so the server case may be removed from the slide rail device; such operation may hurt the user's hand and is inconvenient.

### SUMMARY

Therefore, an object of the disclosure is to provide a slide rail device that can alleviate at least one of the drawbacks of the prior art.

According to the disclosure, the slide rail device is for connecting with a server case. The server case has an engaging member. The slide rail device includes a middle rail and an inner rail unit. The inner rail unit includes an inner rail which is disposed on and longitudinally slidable along the middle rail, a lock member which is disposed on the inner rail, and a releasing member which is disposed on the inner rail and movably connected with the lock member. The inner rail has an inner rail surface facing the middle rail, and an engaging slot formed therethrough for the engaging member to be transversely inserted thereinto. The lock member is engageable with the engaging member to prevent removal of the engaging member from the engaging slot. The releasing member is operably moved longitudinally to abut and press the lock member, which brings deflection of the lock member away from the inner rail surface so as to release engagement of the lock member from the engaging member.

### BRIEF DESCRIPTION OF THE DRAWINGS

Other features and advantages of the disclosure will become apparent in the following detailed description of the embodiments with reference to the accompanying drawings. It is noted that various features may not be drawn to scale.

FIG. 1 is a perspective view illustrating an embodiment of a slide rail device according to the disclosure.

FIG. 2 is an exploded perspective view of the embodiment.

FIG. 3 is a fragmentary perspective view of a middle rail of the embodiment.

FIG. 4 is a fragmentary perspective view of an inner rail unit of the embodiment.

FIG. 5 is a fragmentary, exploded perspective view of the inner rail unit of the embodiment.

FIG. 6 is a side view of a releasing member of the inner rail unit of the embodiment.

FIG. 7 is a bottom view of the releasing member.

FIG. 8 is a fragmentary sectional view taken along line VIII-VIII of FIG. 4.

FIG. 9 is a fragmentary sectional view similar to FIG. 8, illustrating a state when the releasing member moves a lock member away from an inner rail.

FIG. 10 is a fragmentary front view of the inner rail unit of the embodiment.

FIG. 11 is a fragmentary front view similar to FIG. 10, illustrating a state when the releasing member moves the lock member away from the inner rail.

FIG. 12 is a perspective view of a first release operating member of a first stopped and release operating assembly of the inner rail unit of the embodiment.

FIG. 13 is a perspective view of a second release operating member of a second stopped and release operating assembly of the inner rail unit of the embodiment.

FIG. 14 is a perspective view of the embodiment, illustrating a state when the inner rail unit is in an extended position relative to the middle rail.

FIG. 15 is a fragmentary front view of the inner rail unit of the embodiment.

FIG. 16 is a fragmentary front view of the inner rail unit, illustrating a state when the first release operating member is pressed leftwardly to bring a first stopped pivot member to turn downwardly.

FIG. 17 is a fragmentary front view of the inner rail unit, illustrating a state when the second release operating member is pressed leftwardly to bring a second stopped pivot member to turn downwardly.

FIG. 18 is a fragmentary perspective view of an inner rail unit of another embodiment according to the disclosure.

FIG. 19 is a side view of a releasing member of the inner rail unit.

FIG. 20 is a sectional view taken along line XX-XX of FIG. 19.

FIG. 21 is a bottom view of the releasing member.

FIG. 22 is a fragmentary sectional view taken along line XXII-XXII of FIG. 18.

FIG. 23 is a fragmentary sectional view similar to FIG. 22, illustrating a state when the releasing member moves a lock member away from an inner rail.

FIG. 24 is a fragmentary front view of the inner rail unit of the embodiment.

FIG. 25 is a fragmentary front view similar to FIG. 24, illustrating a state when the releasing member moves the lock member away from the inner rail.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

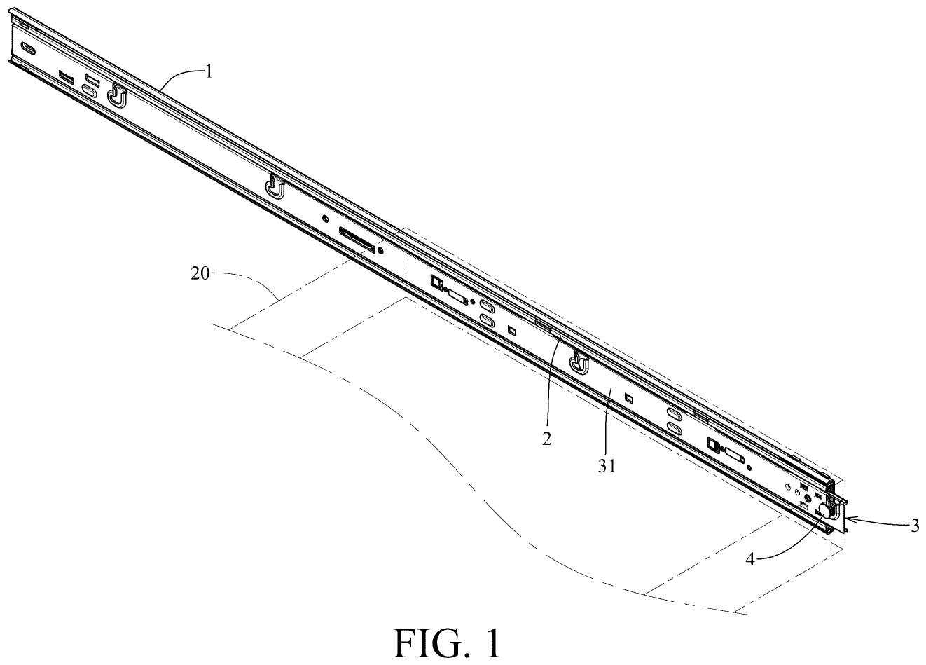

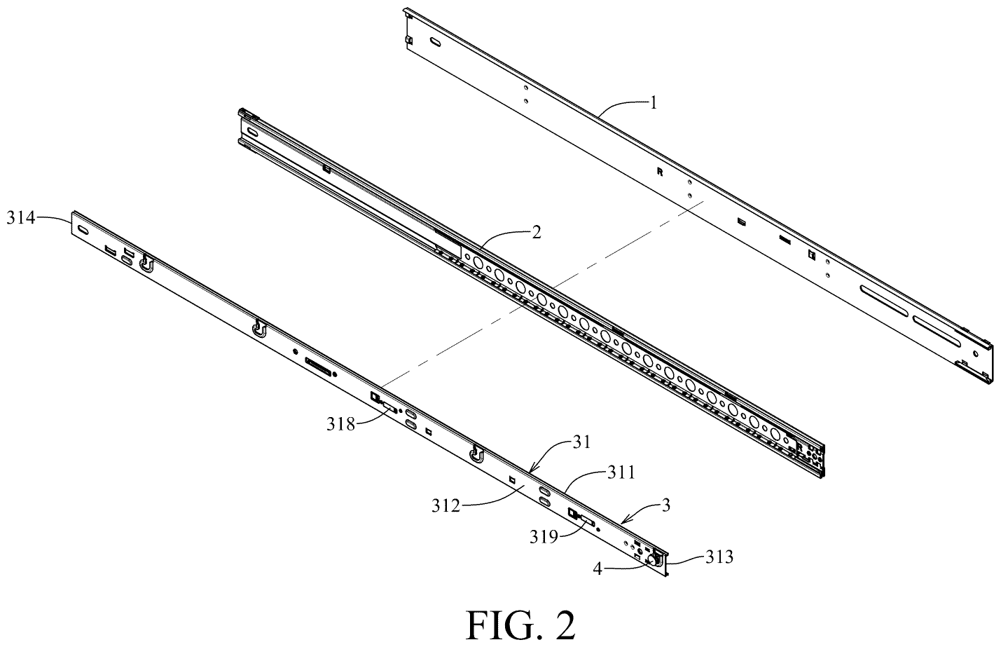

Referring to FIGS. 1 and 2, an embodiment of a slide rail device according to the disclosure is adapted to be mounted on a server rack (not shown) for connecting with and supporting a server case 20. It is noted that a pair of slide rail devices are mounted on the server rack at two sides of the server case 20. The server case 20 has an engaging member 4. The slide rail device includes an outer rail 1, a middle rail 2 and an inner rail unit 3. The outer rail 1 is securely disposed on the server rack. The inner rail unit 3 is connected with a side of the server case 20.

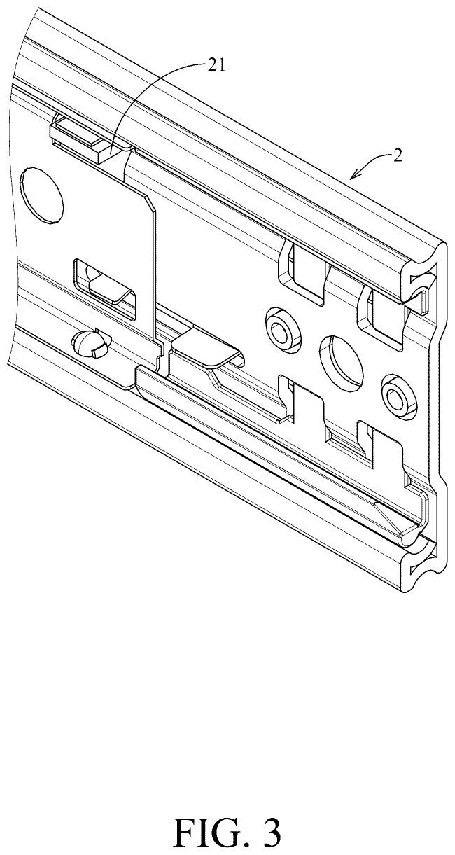

With reference to FIGS. 3 to 5, the inner rail unit 3 includes an inner rail 31 which is disposed on and longitudinally slidable along the middle rail 2, a lock member 32 which is disposed on the inner rail 31, a releasing member 33 which is disposed on the inner rail 31 and movably connected with the lock member 32, a first stopped and release operating assembly 34 which is disposed on the inner rail 31, a second stopped and release operating assembly 35 which is disposed on the inner rail 31, and a return biasing member 36 which is connected between the first and second stopped and release operating assemblies 34, 35. The inner rail 31 has an inner rail surface 311 facing the middle rail 2, an outer rail surface 312 transversely opposite to the inner rail surface 311 and facing the server case 20, a first end 313, a second end 314 longitudinally opposite to the first end 313, an engaging slot 315 formed therethrough and adjacent to the first end 313 for the engaging member 4 of the server case 20 to be transversely inserted thereinto, two releasing slots 316 formed adjacent to the engaging slot 315, two releasing slope surfaces 317 respectively formed in the two releasing slots 316 and engaging the inner rail surface 311, a first guide slot 318 and a second guide slot 319. The engaging slot 315 is located closer to the first end 313 than the releasing slots 316. The middle rail 2 is disposed on and longitudinally slidable along the outer rail 1, and has a stop member 21 which projects toward the inner rail surface 311 of the inner rail 31. It is noted that the engaging slot 315 may be located at any position except the position adjacent to the first end 313.

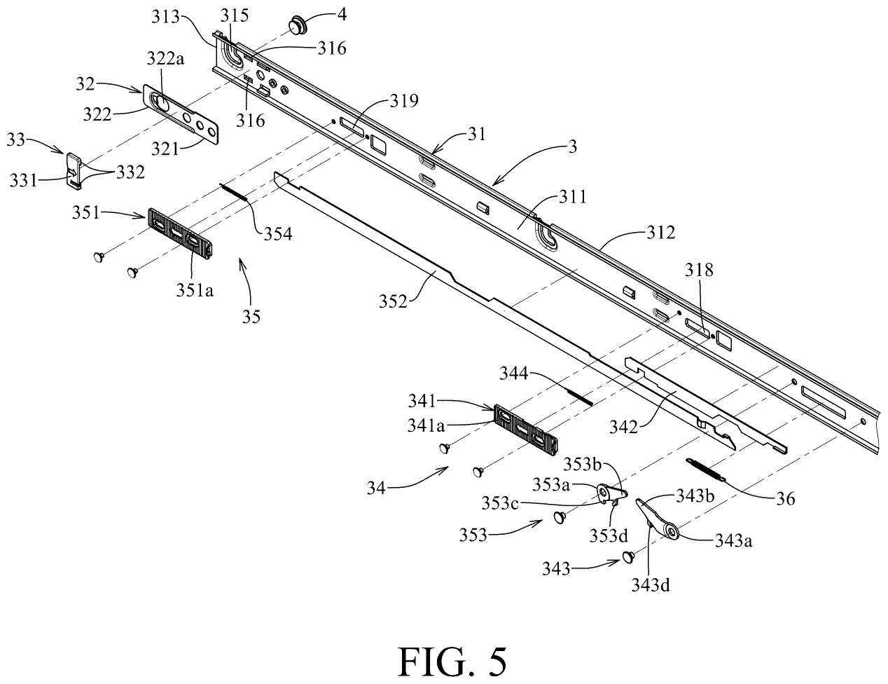

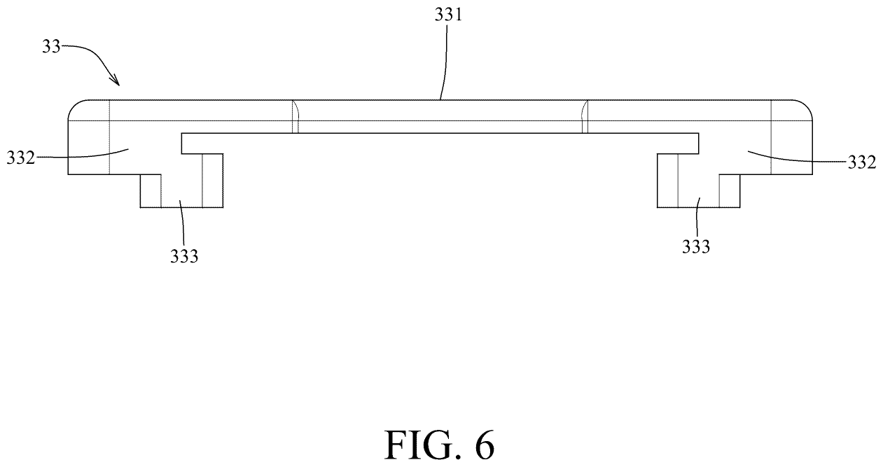

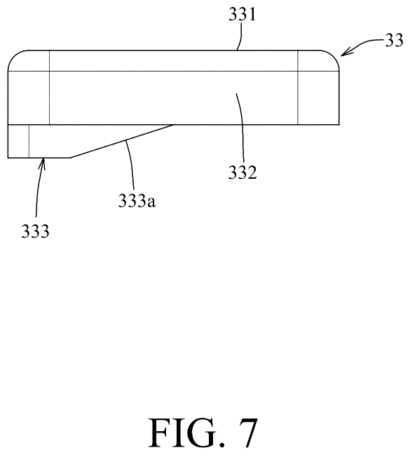

With reference to FIGS. 5 to 7, the lock member 32 is in the form of an elongated plate, and has a mounting portion 321 which is securely mounted on the inner rail surface 311, and an engaging portion 322 which extends longitudinally from the mounting portion 321 to be engageable with the engaging member 4 and is deflectable relative to the mounting portion 321. The engaging portion 322 has a circular engaging hole 322a for the engaging member 4 to be transversely inserted thereinto and to be engaged therein so as to prevent removal of the engaging member 4 from the engaging slot 315. The releasing member 33 has an operating portion 331, two lateral portions 332 which respectively extend from two opposite sides of the operating portion 331 toward the inner rail surface 311, and two abutting portions 333 which respectively extend from the lateral portions 332 toward the inner rail surface 311. The operating portion 331 and the two lateral portions 332 cooperatively and movably straddle the mounting portion 321 of the lock member 32. Each of the two abutting portions 333 is inserted into the corresponding releasing slot 316, and has an abutting slope 333a which is in abutting engagement with the corresponding releasing slope surface 317 of the inner rail 31. In the embodiment, the releasing member 33 is made of a plastic material.

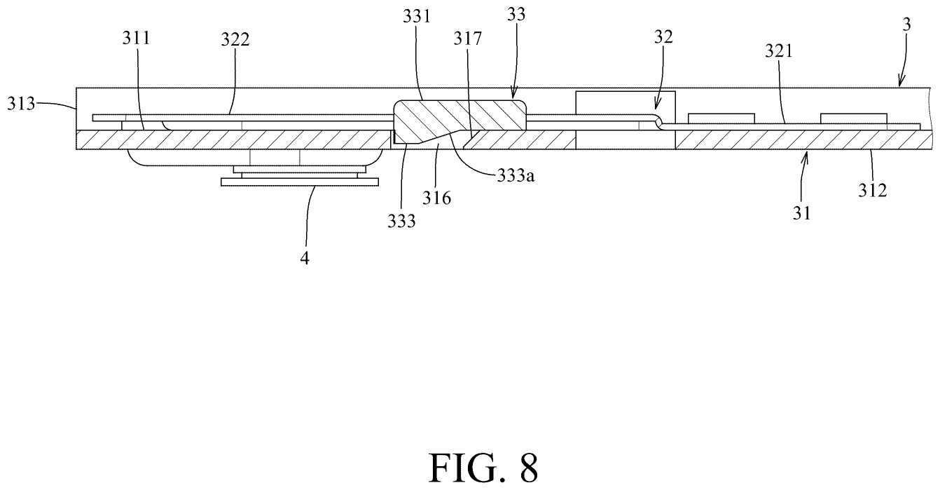

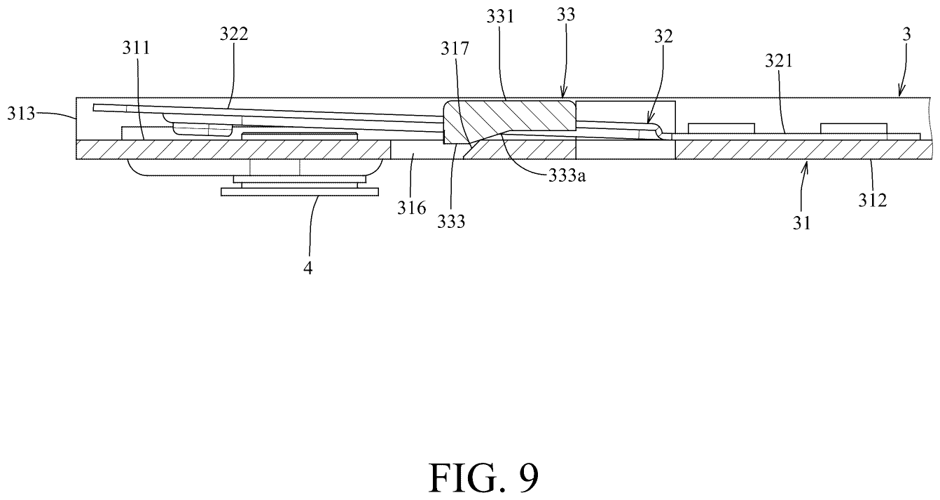

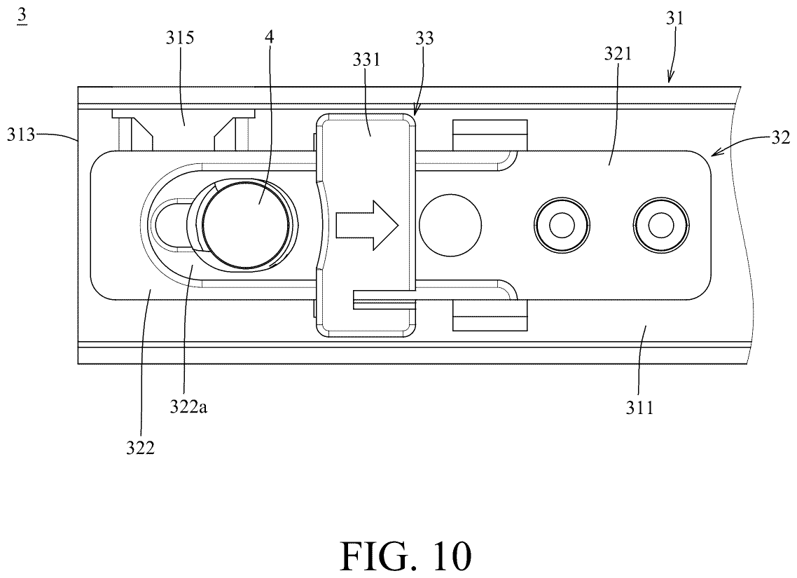

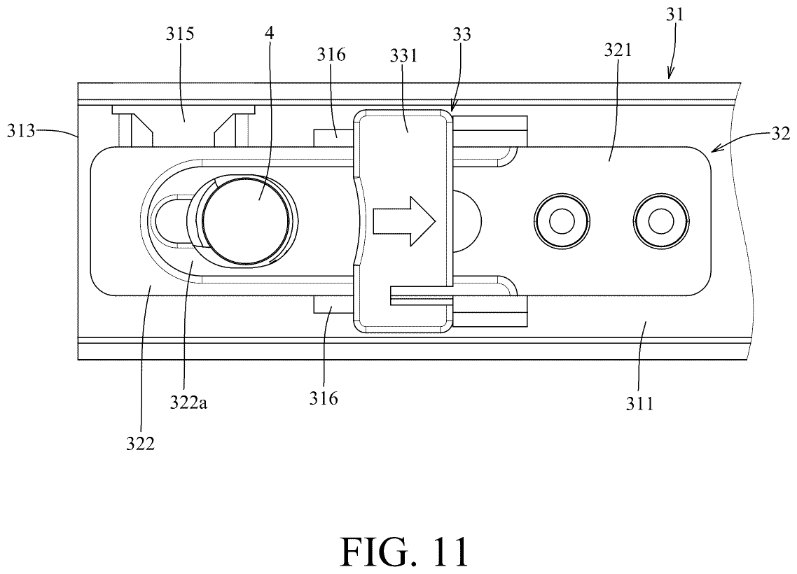

With reference to FIG. 1 and FIGS. 8 to 11, the operating portion 331 of the releasing member 33 is operable to be moved in a direction away from the first end 313 (rightwardly in the drawing) to make the abutting slope 333a abut against the corresponding releasing slope surface 317, which brings movement of the releasing member 33 away from the inner rail surface 311, and deflection of the engaging portion 322 of the lock member 32 away from the inner rail surface 311 so as to release the engagement of the engaging portion 322 from the engaging member 4. In this state, the user can remove the server case 20 and the engaging member 4 from the engaging slot 315 so as to detach the server case 20 from the inner rail 31. Thus, a releasing operation of the engaging portion 322 from the engaging member 4 is easy to conduct through pressing of the operating portion 331 of the releasing member 33. With the releasing member 33 made of a plastic material, the risk of scratching the user's hands during the releasing operation is reduced.

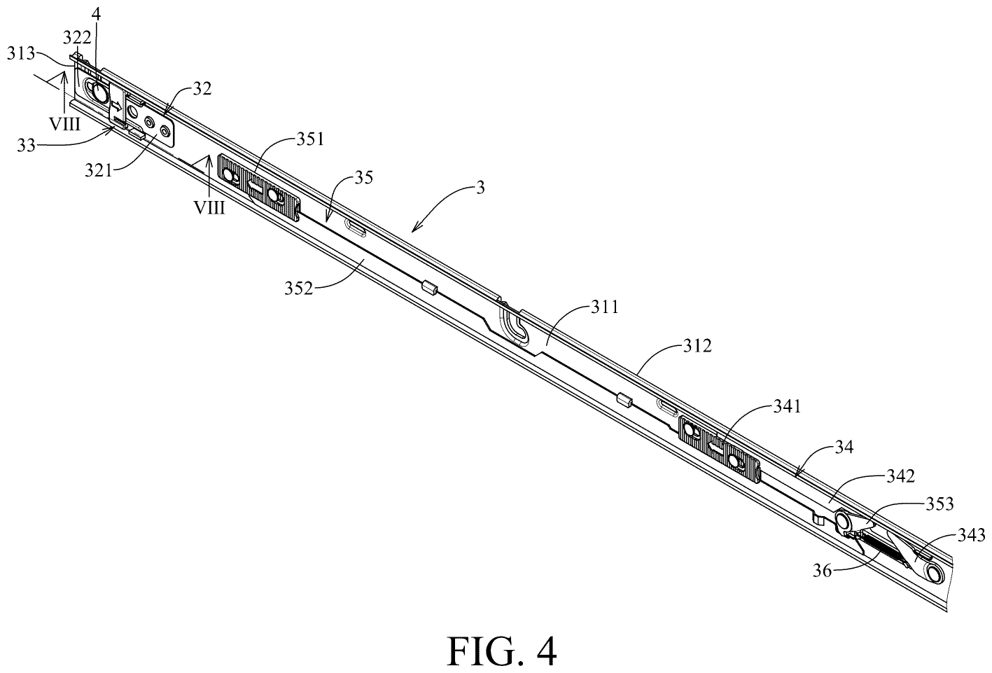

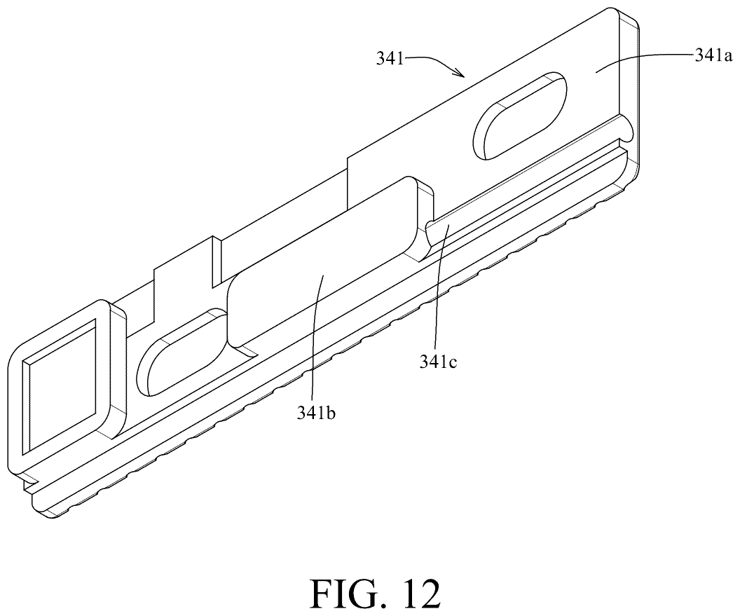

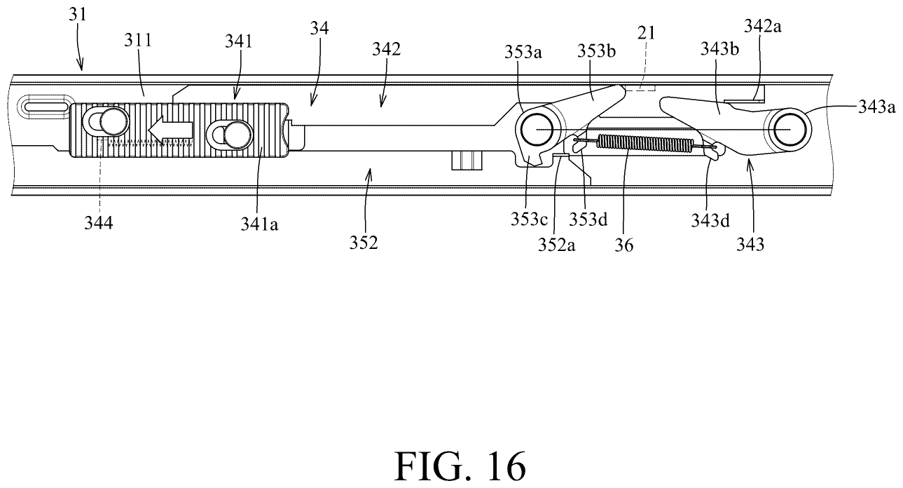

With reference to FIGS. 4, 5 and 12, the first stopped and release operating assembly 34 includes a first release operating member 341 which is movably disposed on the inner rail 31, a first release transmitting member 342 which is connected and moved with the first release operating member 341, a first stopped pivot member 343 which is pivotably disposed on the inner rail 31 to be stopped by and engaged with the stop member 21 when the inner rail unit 3 slides along the middle rail 2 in an extended direction, and a first biasing member 344 which is disposed between the inner rail 31 and the first release operating member 341 to bias the first release operating member 341 to return to an original position thereof. Specifically, the first release operating member 341 has a plate portion 341a which is disposed parallel to the inner rail surface 311, a key portion 341b which protrudes from the plate portion 341a toward the inner rail surface 311 to be inserted into the first guide slot 318, and a spring receiving slot 341c which is formed between the plate portion 341a and the key portion 341b for receiving the first biasing member 344 therein. The first biasing member 344 has a portion received in the first guide slot 318, and an end in abutting engagement with the inner rail 31. The first stopped pivot member 343 has a pivot portion 343a pivotably connected with the inner rail surface 311, a stopped portion 343b extending upwardly from and inclined relative to the pivot portion 343a and in abutting engagement with an upper edge of the inner rail 31 (see FIG. 4), and a hook portion 343d disposed on the stopped portion 343b adjacent to the pivot portion 343a. The first release transmitting member 342 is an elongated plate which has a thrust end portion 342a in abutting engagement with the stopped portion 343b (see FIG. 16).

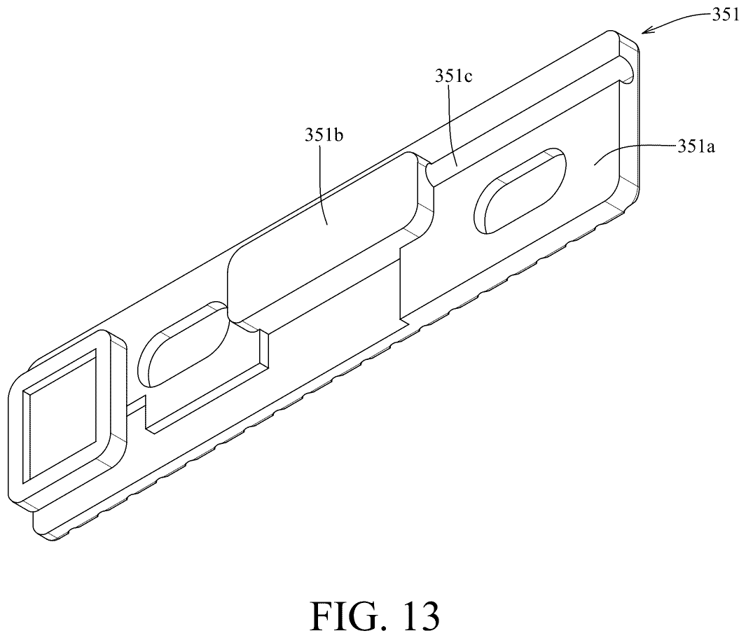

With reference to FIGS. 4, 5 and 13, the second stopped and release operating assembly 35 includes a second release operating member 351 which is movably disposed on the inner rail 31, a second release transmitting member 352 which is connected and moved with the second release operating member 351, a second stopped pivot member 353 which is pivotably disposed on the inner rail 31 to be stopped by and engaged with the stop member 21 when the inner rail unit 3 slides along the middle rail 2 in a retreating direction, and a second biasing member 354 which is disposed between the inner rail 31 and the second release operating member 351 to bias the second release operating member 351 to return to an original position thereof. Specifically, the second release operating member 351 has a plate portion 351a which is disposed parallel to the inner rail surface 311, a key portion 351b which protrudes from the plate portion 351a toward the inner rail surface 311 to be inserted into the second guide slot 319, and a spring receiving slot 351c which is formed between the plate portion 351a and the key portion 351b for receiving the second biasing member 354 therein. The second biasing member 354 has a portion received in the second guide slot 319, and an end in abutting engagement with the inner rail 31. The second stopped pivot member 353 has a pivot portion 353a pivotably connected with the inner rail surface 311, a stopped portion 353b extending upwardly from and inclined relative to the pivot portion 353a and in abutting engagement with an upper edge of the inner rail 31 (see FIG. 4), an actuated portion 353c extending downwardly from the pivot portion 353a, and a hook portion 353d disposed on the stopped portion 353b adjacent to the pivot portion 353a. The second release transmitting member 352 is an elongated plate which has a thrust end portion 352a in abutting engagement with the actuated portion 353c (see FIG. 16). The return biasing member 36 has two ends respectively connected with the hook portions 343d, 353d of the first and second stopped pivot members 343, 353 to bias the first stopped pivot member 343 to return to an original position thereof and to bias the second stopped pivot member 353 to return to an original position thereof.

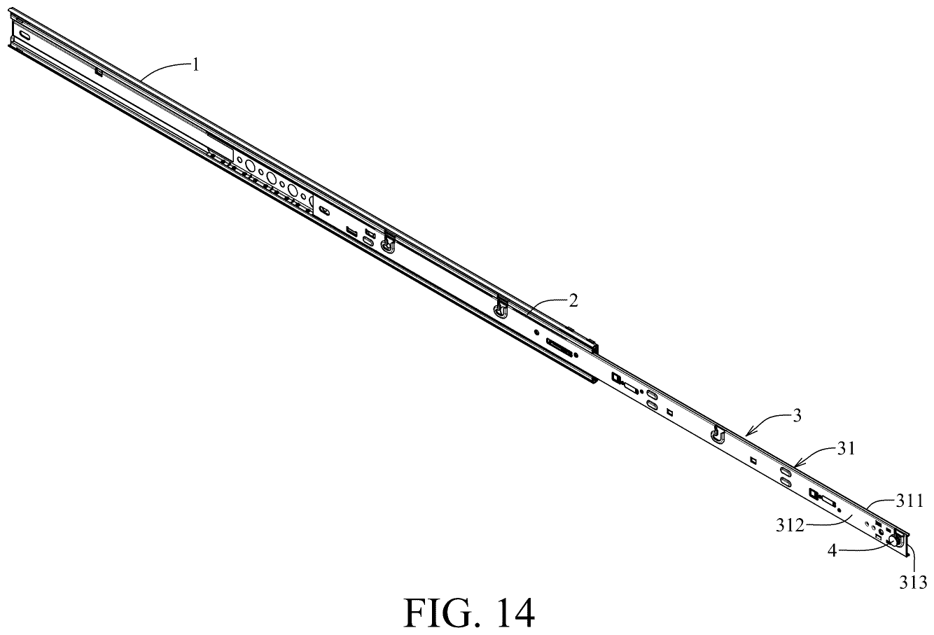

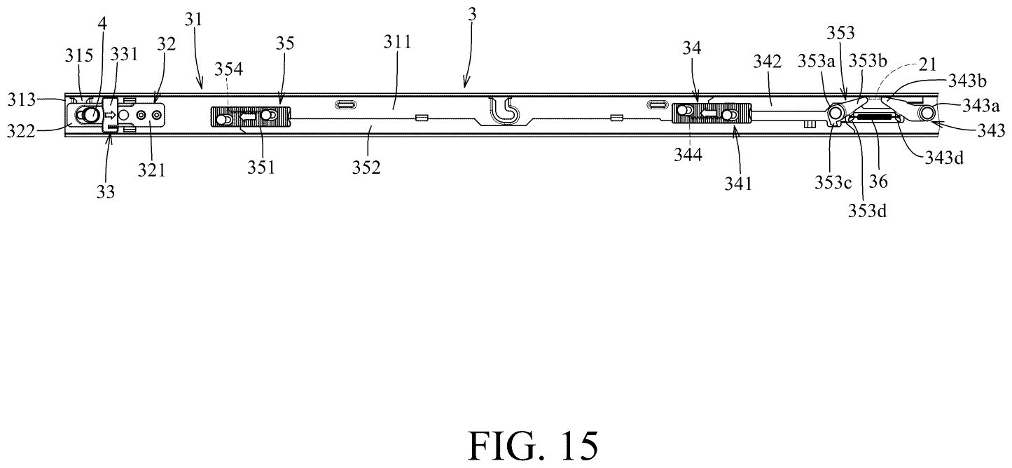

With reference to FIG. 1 and FIGS. 14 to 16, the inner rail unit 3 is slidable relative to the middle rail 2 to an extended position, as shown in FIG. 14. In this position, as shown in FIG. 15, the first and second stopped pivot members 343, 353 are stopped by and engaged with the stop member 21 of the middle rail 2 so as to position the inner rail 31 relative to the middle rail 2 to restrict a pull-out movement of the inner rail 31 relative to the middle rail 2 and to prevent undesired removal of the inner rail unit 3 from the middle rail 2. Also, a retreating movement of the inner rail unit 3 to the middle rail 2 is prevented. For conducting maintenance work of the server case 20, it is required to remove the server case 20 and the inner rail unit 3 from the middle rail 2, and then perform the previous described releasing operation. Firstly, the first release operating member 341 is pressed leftwardly to move the first release transmitting member 342 leftwardly such that the thrust end portion 342a abuts and presses the stopped portion 343b to turn the first stopped pivot member 343 downwardly so as to release the engagement of the inner rail unit 3 from the stop member 21 to permit a pull-out movement (a leftward movement in the drawing) of the inner rail unit 3 relative to the middle rail 2, as shown in FIG. 16. During the leftward operation of the first release operating member 341, the first biasing member 344 is compressed to bias the first release operating member 341 to return to the original position thereof when the leftward operation is stopped, and the first stopped pivot member 343 is turned back to an original position thereof.

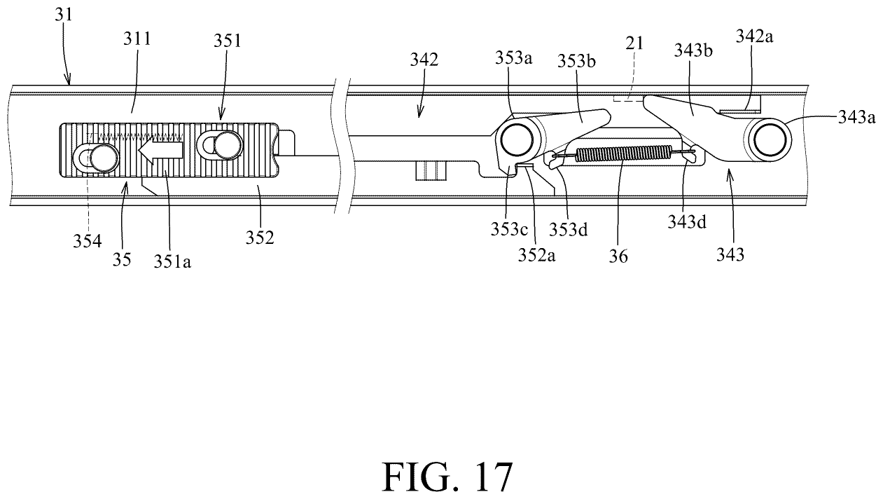

With reference to FIGS. 1, 15 and 17, thereafter, when it is desired to assemble the inner rail unit 3 back to the middle rail 2, the server case 20 and the inner rail unit 3 are pressed rightwardly toward the middle rail 2, and the second release operating member 351 is pressed leftwardly to move the second release transmitting member 352 leftwardly such that the thrust end portion 352a abuts and presses the actuated portion 353c to turn the second stopped pivot member 353 downwardly so as to release the engagement of the inner rail unit 3 from the stop member 21 and to permit the retreating movement (a rightward movement in the drawing) of the inner rail unit 3 relative to the middle rail 2, as shown in FIG. 17. During the leftward operation of the second release operating member 351, the second biasing member 354 is compressed to bias the second release operating member 351 to return to an original position thereof when the leftward operation is stopped, and the second stopped pivot member 353 is turned back to an original position thereof.

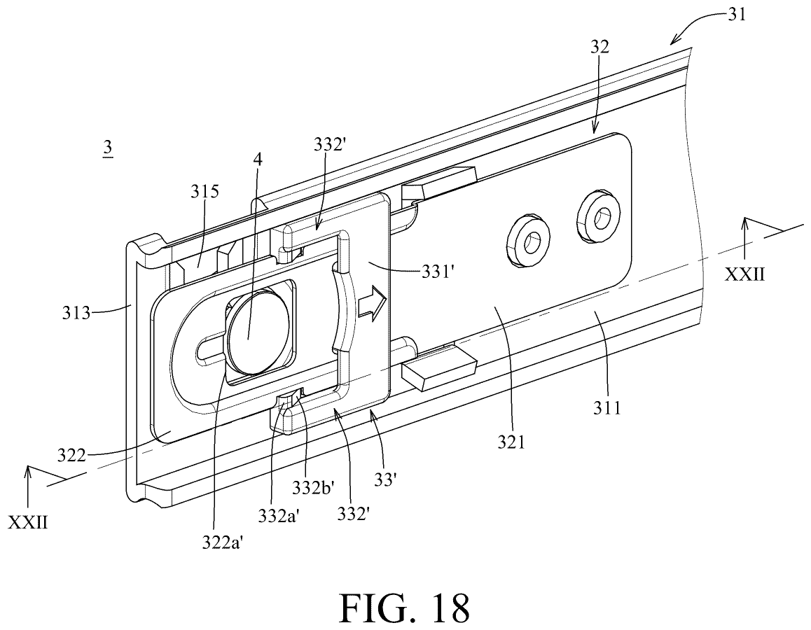

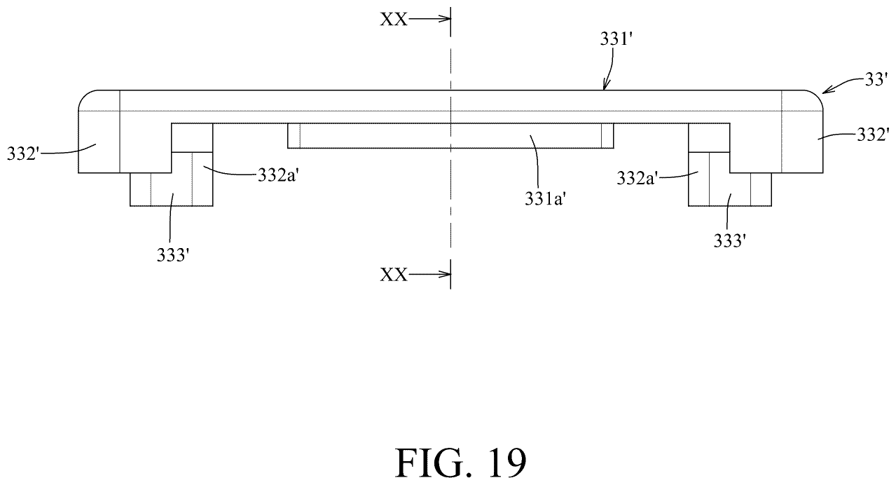

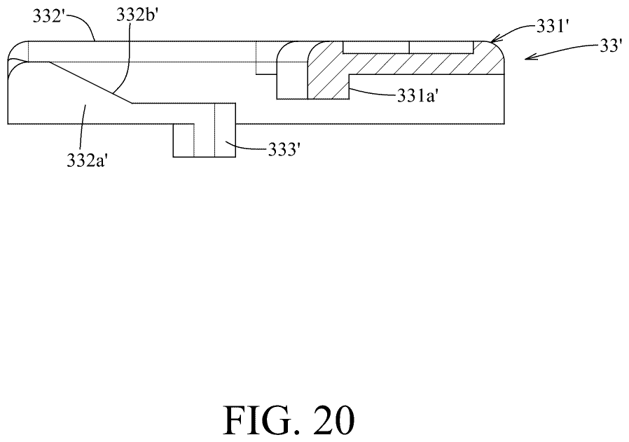

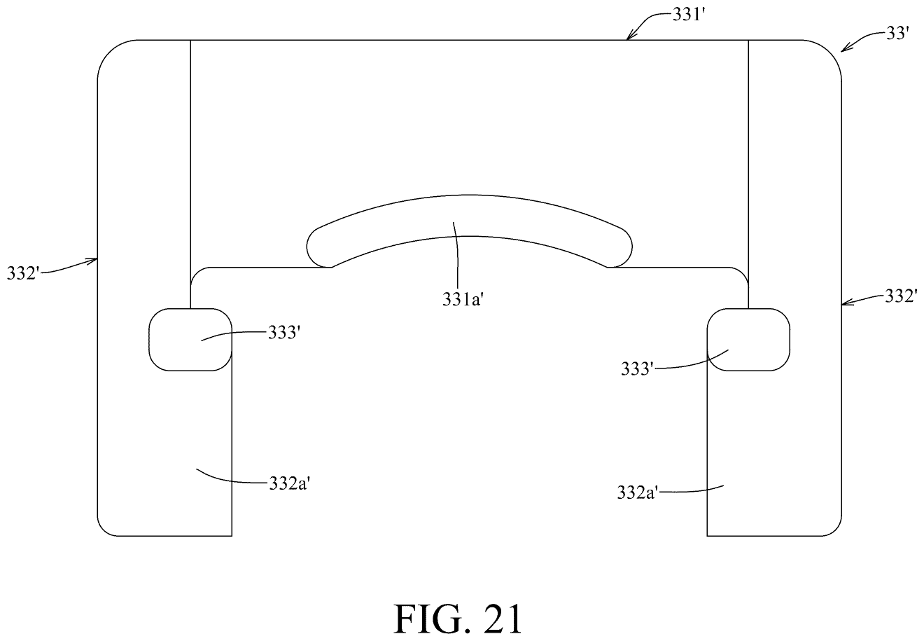

With reference to FIGS. 18 to 21, in another embodiment, the engaging portion 322 of the lock member 32 has a square engaging hole 322a′. The releasing member 33′ has an operating portion 331′, two lateral portions 332′ which respectively extend from two opposite sides of the operating portion 331′ toward the inner rail surface 311, and two abutting portions 333′ which respectively extend from the lateral portions 332′ toward the inner rail surface 311 and which are respectively inserted into the releasing slots 316. The releasing slots 316 are free of releasing slope surfaces 317. The operating portion 331′ and the two lateral portions 332′ cooperatively and movably straddle the mounting portion 321 of the lock member 32. In this embodiment, the operating portion 331′ has an arcuate rib 331a′ extending downwardly to abut against the mounting portion 321. The two lateral portions 332′ respectively have two abutting protrusions 332a′ which extend toward each other. Each of the two abutting protrusions 332a′ has an abutting slope 332b′ which is in abutting engagement with the mounting portion 321.

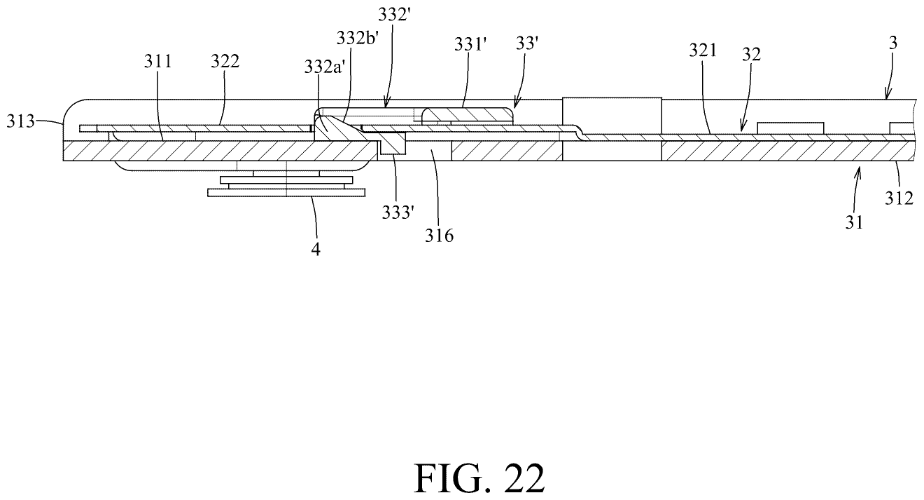

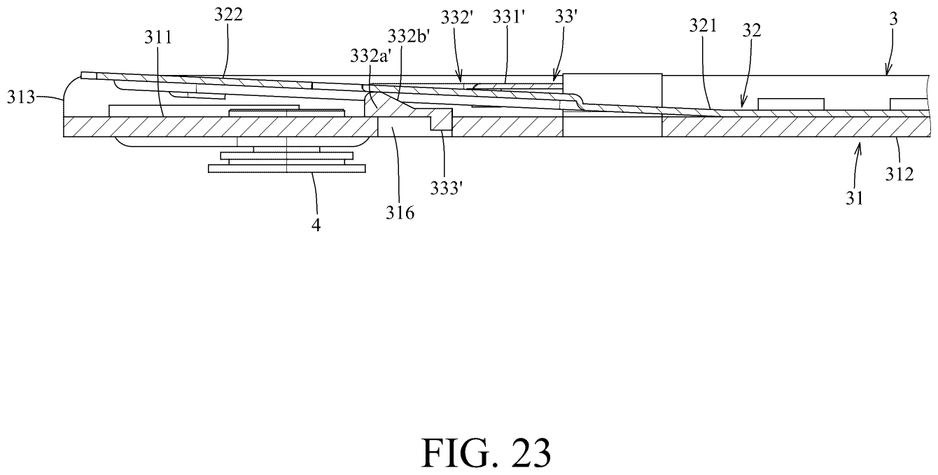

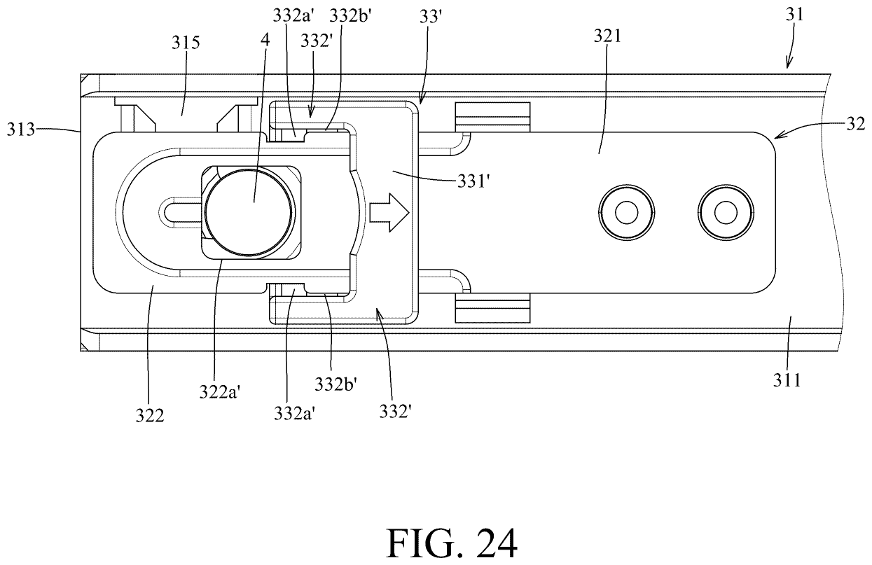

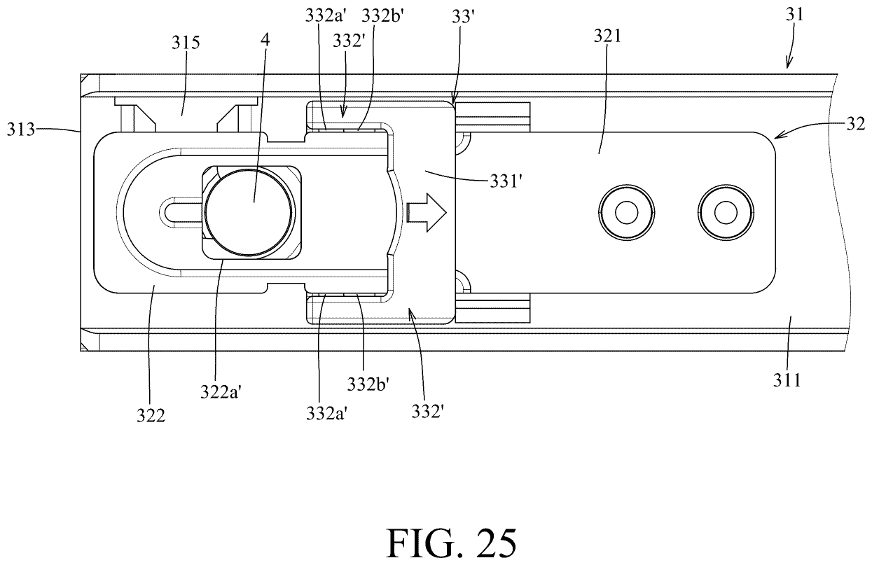

With reference to FIG. 1 and FIGS. 22 to 25, the operating portion 331′ is operably moved in a direction away from the first end 313 to make the abutting slopes 332b′ abut against the mounting portion 321 such that the engaging portion 322 of the lock member 32 is deflected upwardly away from the inner rail surface 311 to release the engagement of the engaging portion 322 from the engaging member 4. At this time, the server case 20 and the engaging member 4 are permitted to be removed from the inner rail 31. Thus, a releasing operation of the engaging portion 322 from the engaging member 4 is easy to conduct through pressing of the operating portion 331′ of the releasing member 33'. With the releasing member 33′ made of a plastic material, the risk of scratches on the user's hands during the releasing operation is reduced.

As illustrated, with the releasing member 33, 33′ operably moved to abut and press the lock member 32, the lock member 32 is deflected away from the inner rail surface 311 so as to release the engagement of the lock member 32 from the engaging member 4 of the server case 20. The server case 20 and the engaging member 4 are thus permitted to be removed from the inner rail 31. The releasing operation of the engaging portion from the engaging member is easy to conduct.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A slide rail device for connecting with a server case, the server case having an engaging member, comprising:
a middle rail; and
an inner rail unit including an inner rail which is disposed on and longitudinally slidable along said middle rail, a lock member which is disposed on said inner rail, and a releasing member which is disposed on said inner rail and movably connected with said lock member, said inner rail having an inner rail surface facing said middle rail, and an engaging slot formed therethrough for the engaging member to be transversely inserted thereinto, said lock member being engageable with the engaging member to prevent removal of the engaging member from said engaging slot, said releasing member being operably moved longitudinally to abut and press said lock member, which brings deflection of said lock member away from said inner rail surface so as to release engagement of said lock member from the engaging member.

2. The slide rail device of claim 1, wherein said lock member has a mounting portion which is securely mounted on said inner rail surface, and an engaging portion which extends longitudinally from said mounting portion to be engageable with the engaging member and is deflectable relative to said mounting portion, said engaging portion having an engaging hole for the engaging member to be transversely inserted thereinto and to be engaged therein.

3. The slide rail device of claim 2, wherein said inner rail has a first end and two releasing slots, said engaging slot being located closer to said first end than said releasing slots, said releasing member having an operating portion, two lateral portions which respectively extend from two opposite sides of said operating portion toward said inner rail surface, and two abutting portions which respectively extend from said lateral portions toward said inner rail surface, said operating portion and said two lateral portions cooperatively and movably straddling said mounting portion, each of said two abutting portions being inserted into a respective one of said releasing slots, and having an abutting slope which is in abutting engagement with said inner rail, wherein said operating portion is operably moved in a direction away from said first end to make an abutting engagement of said abutting slope with said inner rail, which brings movement of said releasing member away from said inner rail surface, and deflection of said engaging portion of said lock member away from said inner rail surface so as to release engagement of said engaging portion from the engaging member.

4. The slide rail device of claim 2, wherein said inner rail has a first end and two releasing slots, said engaging slot being located closer to said first end than said releasing slots, said releasing member having an operating portion, two lateral portions which respectively extend from two opposite sides of said operating portion toward said inner rail surface, and two abutting portions which respectively extend from said lateral portions toward said inner rail surface and which are respectively inserted into said releasing slots, said operating portion and said two lateral portions cooperatively and movably straddling said mounting portion, said two lateral portions respectively having two abutting protrusions which extend toward each other, each of said two abutting protrusions having an abutting slope which is in abutting engagement with said mounting portion, wherein said operating portion is operably moved in a direction away from said first end to make said abutting slopes abut against said mounting portion, which brings deflection of said engaging portion of said lock member away from said inner rail surface so as to release engagement of said engaging portion from the engaging member.

5. The slide rail device of claim 1, wherein said middle rail has a stop member which projects toward said inner rail surface of said inner rail, said inner rail unit further including a first stopped and release operating assembly which is disposed on said inner rail, said first stopped and release operating assembly including a first release operating member which is movably disposed on said inner rail, a first release transmitting member which is connected and moved with said first release operating member, and a first stopped pivot member which is pivotably disposed on said inner rail to be stopped by and engaged with said stop member when said inner rail unit slides along said middle rail in an extended direction, wherein said first release transmitting member is in abutting engagement with said first stopped pivot member such that said first release operating member is operable to move said first release transmitting member, which turns said first stopped pivot member so as to release engagement of said first stopped pivot member from said stop member.

6. The slide rail device of claim 5, wherein said first stopped and release operating assembly further includes a first biasing member which is disposed between said inner rail and said first release operating member to bias said first release operating member to return to an original position thereof.

7. The slide rail device of claim 6, wherein said inner rail has a first guide slot, said first release operating member having a plate portion which is disposed parallel to said inner rail surface, a key portion which protrudes from said plate portion toward said inner rail surface to be inserted into said first guide slot, and a spring receiving slot which is formed between said plate portion and said key portion for receiving said first biasing member therein, said first biasing member having a portion received in said first guide slot and an end in abutting engagement with said inner rail.

8. The slide rail device of claim 7, wherein said inner rail unit further includes a second stopped and release operating assembly which is disposed on said inner rail, said second stopped and release operating assembly including a second release operating member which is movably disposed on said inner rail, a second release transmitting member which is connected and moved with said second release operating member, and a second stopped pivot member which is pivotably disposed on said inner rail to be stopped by and engaged with said stop member when said inner rail unit slides along said middle rail in a retreating direction, wherein said second release transmitting member is in abutting engagement with said second stopped pivot member such that said second release operating member is operable to move said second release transmitting member, which turns said second stopped pivot member so as to release engagement of said second stopped pivot member from said stop member.

9. The slide rail device of claim 8, wherein said second stopped and release operating assembly further includes a second biasing member which is disposed between said inner rail and said second release operating member to bias said second release operating member to return to an original position thereof.

10. The slide rail device of claim 9, wherein said inner rail has a second guide slot, said second release operating member having a plate portion which is disposed parallel to said inner rail surface, a key portion which protrudes from said plate portion toward said inner rail surface to be inserted into said second guide slot, and a spring receiving slot which is formed between said plate portion and said key portion for receiving said second biasing member therein, said second biasing member having a portion received in said second guide slot and an end in abutting engagement with said inner rail.
